(19) United States
(12) Patent Application Publication
(10) Pub. No.: US 2008/0300806 A1
(43) Pub. Date: Dec. 4, 2008

(54) Power consumption calculating method

(75) Inventor: Sanae Nakanishi, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/155,082

(22) Filed: May 29, 2008

(30) Foreign Application Priority Data
May 30, 2007 (JP) 2007-142826

(51) Int. Cl. G01R 21/00

(52) U.S. Cl. 702/61

(57) ABSTRACT

A power consumption calculating method comprises: generating operation information; obtaining functional block power consumption; and obtaining entire power consumption of an integrated circuit. The operation information indicates operation of a functional block. The operation information is generated based on a low-level circuit model by configuring the low-level circuit model from a behavioral-level circuit model describing the integrated circuit at a behavioral level. The behavioral-level circuit model has at least one functional block including the functional block. The low-level circuit model describes the integrated circuit at lower degree of abstraction than the behavioral level. The functional block power consumption is obtained as power consumption of the functional block based on the operation information and element power consumption as power consumption of element group constituting the functional block. The entire power consumption is obtained based on the functional block power consumption and number of times the functional block is executed in operation of the integrated circuit.

### INCORPORATION BY REFERENCE

This application is based upon and claims the benefit of priority from Japanese patent application No. 2007-142826, filed on May 30, 2007, the disclosure of which is incorporated herein in its entirely by reference.

### BACKGROUND OF THE INVENTION

1. Field of the Invention

The present invention relates to a method, program and apparatus for calculating power consumption, and particularly to a method, program and apparatus for calculating power consumption of an integrated circuit based on a behavioral-level model of the integrated circuit, a library usable in the apparatus, and a method for generating the library.

2. Description of Related Art

As semiconductor technology progresses, circuit scale has been increased in semiconductor devices such as system large scale integration (LSI). As a method to design a semiconductor device having a large circuit scale, there is known a top-down design method in which a design is implemented from a higher degree of abstraction to a lower degree of abstraction. In the top-down design method, a semiconductor device is often designed at three levels: a behavioral level, a resister transfer (RT) level and a gate level. In designing semiconductor device, the semiconductor device as an object of design is subjected to verifications of operation, throughput, power consumption and the like by simulations.

Semiconductor devices mounted to electronic equipments are required to have low power consumption. Therefore, there are known methods to verify power consumption of semiconductor devices at a design stage (e.g. refer to “ORINOCO Behavioral Level Low Power Estimation” <http://www.chipvision.com/> and Japanese Laid Open Patent Application (JP-P2005-293163A)).

FIG. 1 is a flowchart illustrating a power consumption estimating method disclosed in “ORINOCO Behavioral Level Low Power Estimation”. In the method disclosed in “ORINOCO Behavioral Level Low Power Estimation”, a routine for calculating operating ratio is inserted into a first algorithm description 141 described at the behavioral level to obtain a second algorithm description 142 (step S1), and the second algorithm description 142 is simulated (step S2). A control data flow graph (CDFG) is generated from the second algorithm description 142 (step 3). The CDFG is a data structure generated by a behavioral synthesis from the second algorithm description 142. The CDFG is generated by a process to convert the algorithm description to a cycle behavior. The process may be referred to as scheduling.

An operating-ratio file 143 obtained by the simulation at the step S2 is assigned to the CDFG generated at the step S3 (step S4), constraints for number of resources, timings and the like are set, and a process is executed which corresponds to a binding process carried out in the behavioral synthesis (step S5). According to “ORINOCO Behavioral Level Low Power Estimation”, power consumption of the object of design is estimated at a higher level than the RT level based on environment constructed as described above (step S6).

Japanese Laid Open Patent Application (JP-P2005-293163A) discloses one of methods to calculate at high speed a predicted value of power consumption of a semiconductor device as an object of design. FIG. 2 illustrates a method to calculate a predicted value of power consumption by a power consumption estimating apparatus 100 disclosed in Japanese Laid Open Patent Application (JP-P2005-293163A). Referring to FIG. 2, in the power consumption estimating apparatus 100, a behavioral synthesizer 101 performs a behavioral synthesis based on an algorithm description 111 to generate a clock-level description 113. The clock-level description 113 is then simulated by a clock-level simulator 102 based on a simulation description 115 to calculate operating ratios of storage elements and computing elements indicated by the clock-level description 113.

A storage-element power calculating section 103 calculates a predicted value of power consumption corresponding to the storage elements based on power calculation formulae read from a power calculation formula file 116 and the operating ratios of the storage elements. A combinational-circuit power calculating section 104 calculates a predicted value of power consumption corresponding to the computing elements based on power calculation formulae read from the power calculation formula file 116 and the operating ratios of the computing elements. The combinational-circuit power calculating section 104 calculates a predicted value of power consumption corresponding to combinational circuits other than the computing elements based on power calculation formulae read from the power calculation formula file 116, the operating ratios of the storage elements and the computing elements, and operating ratios of input and output ports.

Japanese Laid Open Patent Application (JP-P2001-109788A) discloses a method to allow simulations at an intermediate level between an algorithm-level description and an RT-level description.

In the method disclosed in “ORINOCO Behavioral Level Low Power Estimation”, the power consumption is estimated by executing the simulation at a level higher than the RT level. More specifically, the operating ratios are calculated by executing the simulation at the behavioral level, and the operating ratios are used to estimate the power consumption in the environment constructed through the generation of the CDFG and the binding process.

The algorithm description in the method disclosed in “ORINOCO Behavioral Level Low Power Estimation” is an untimed description without time setting. Therefore, accuracy of estimating power consumption may be low in comparison with a case where a hardware model is simulated dynamically. Moreover, the method disclosed in “ORINOCO Behavioral Level Low Power Estimation” does not assure that the environment constructed through the generation of the CDFG and the binding process corresponds to an RT-level (RTL) description obtained later by performing behavioral synthesis based on the algorithm description. Therefore, it may be difficult to accurately estimate power consumption of a semiconductor device as an object of design.

The method disclosed in Japanese Laid Open Patent Application (JP-P2005-293163A) is capable of calculating a predicted value of power consumption of a semiconductor device as an object of design at higher speed than that in the method disclosed in “ORINOCO Behavioral Level Low Power Estimation”. Circuit scale has been increased in semiconductor devices such as system LSI. Increased circuit scale of semiconductor devices results in a longer period of time spent for the verifications through simulations at design stage.

In order to design a semiconductor device in a short period, it is demanded to estimate power consumption of a semiconductor device as an object of design at higher speed.

### SUMMARY

In one embodiment, a power consumption calculating method comprises: generating operation information; obtaining functional block power consumption; and obtaining entire power consumption of an integrated circuit. The operation information indicates operation of a functional block. The operation information is generated based on a low-level circuit model by configuring the low-level circuit model from a behavioral-level circuit model describing the integrated circuit at a behavioral level. The behavioral-level circuit model has at least one functional block including the functional block. The low-level circuit model describes the integrated circuit at lower degree of abstraction than the behavioral level. The functional block power consumption is obtained as power consumption of the functional block based on the operation information and element power consumption as power consumption of element group constituting the functional block. The entire power consumption is obtained based on the functional block power consumption and number of times the functional block is executed in operation of the integrated circuit.

In another embodiment, a computer-readable recording medium which records a program that when executed causes a computer to perform a method comprising: generating operation information; obtaining functional block power consumption; and obtaining entire power consumption of an integrated circuit. The operation information indicates operation of a functional block. The operation information is generated based on a low-level circuit model by configuring the low-level circuit model from a behavioral-level circuit model describing the integrated circuit at a behavioral level. The behavioral-level circuit model has at least one functional block including the functional block. The low-level circuit model describes the integrated circuit at lower degree of abstraction than the behavioral level. The functional block power consumption is obtained as power consumption of the functional block based on the operation information and element power consumption as power consumption of element group constituting the functional block. The entire power consumption is obtained based on the functional block power consumption and number of times the functional block is executed in operation of the integrated circuit.

In another embodiment, a library generating method comprising: specifying a functional block as an object of generating a library from a plurality of functional blocks; generating operation information; and configuring the library. The plurality of functional blocks are included in an integrated circuit model described at a behavioral level. The operation information indicates operation of the functional block and is generated based on a low-level intellectual property (IP) model by behavioral-synthesizing an intellectual property (IP) model including the functional block specified and by describing the low-level IP model including time information indicating required time of operation of the functional block at lower degree of abstraction than the behavioral level. The functional block power calculation formula indicates power consumed in the functional block and is generated based on the operation information and a power calculation formula indicating power consumed in element group constituting the functional block. The library is configured by generating a functional block power calculation formula for each of the plurality of functional blocks.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a flowchart illustrating a power consumption estimating method according to related art;

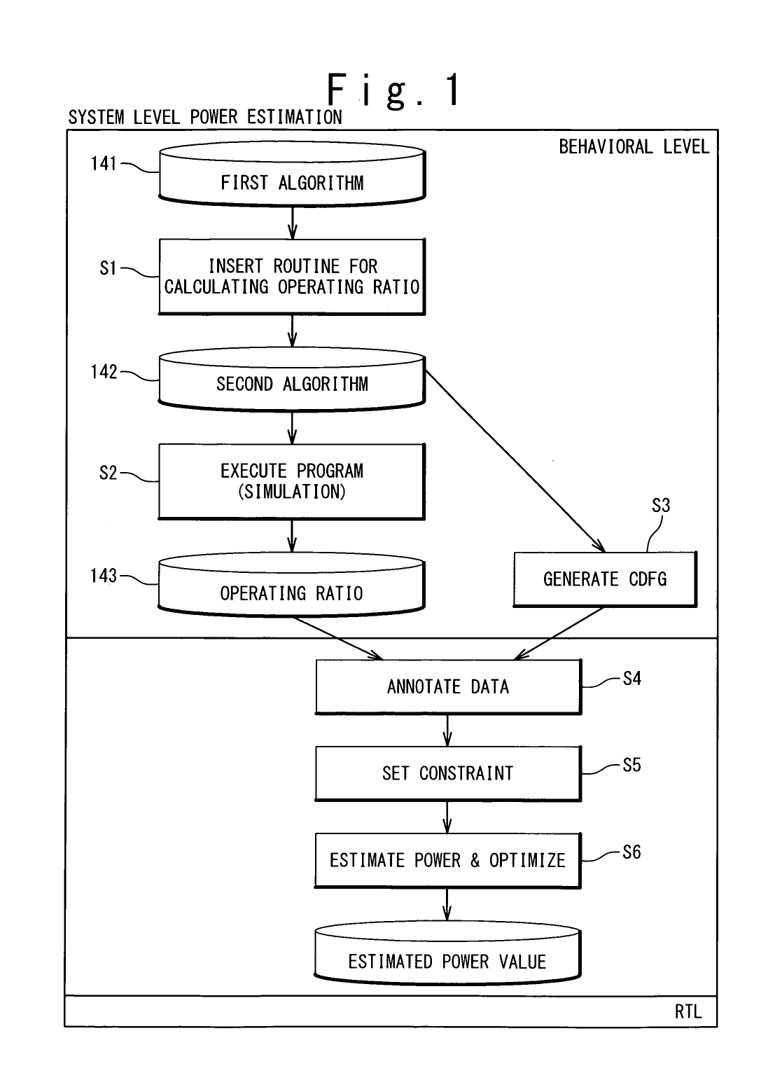

FIG. 2 illustrates a method to calculate a predicted value of power consumption by a power consumption estimating apparatus according to another related art;

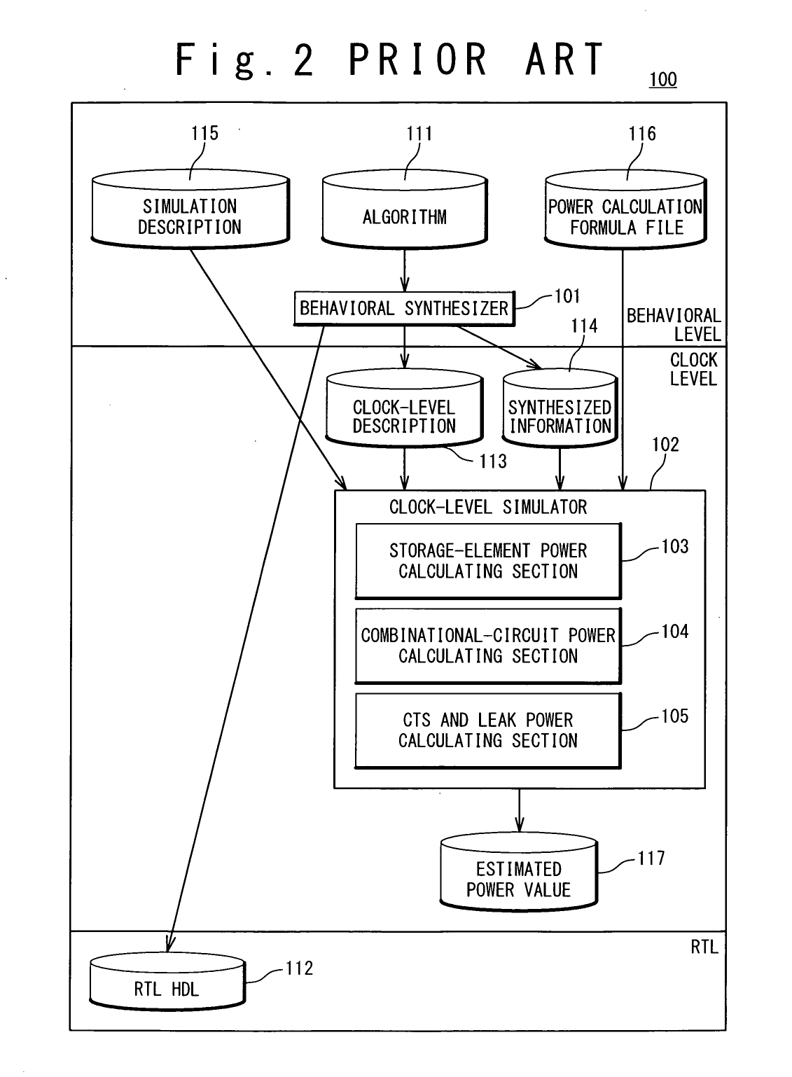

FIG. 3 is a block diagram of a power consumption calculating apparatus according to a first embodiment of the present invention;

FIG. 4 is a flowchart illustrating operation of the power consumption calculating apparatus;

FIG. 5 shows a behavioral-level C description list extracted from a behavioral-level C description;

FIG. 6 is a table showing control information outputted from a behavioral synthesis tool;

FIG. 7 is a list showing a clock-level description; and

FIG. 8 shows an estimated power consumption data table 36.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

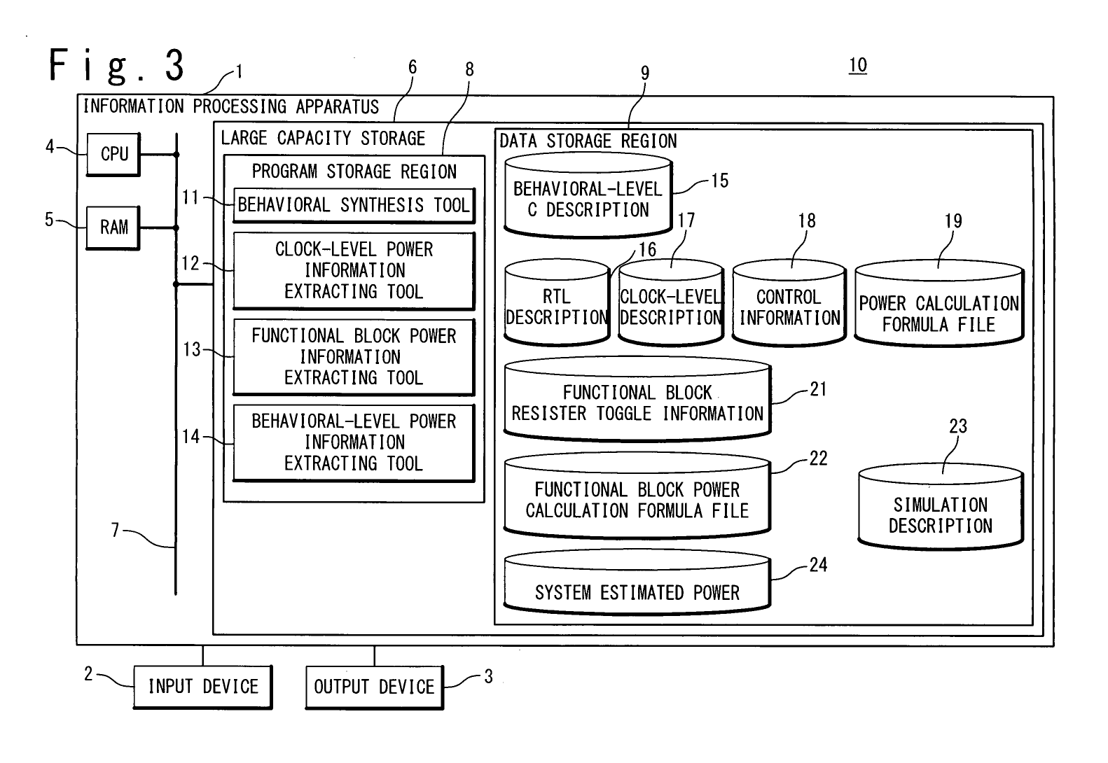

FIG. 3 is a block diagram showing a power consumption calculating apparatus 10 according to a first embodiment of the present invention.

Referring to FIG. 3, the power consumption calculating apparatus 10 includes information processing apparatus 1, an input device 2, and an output device 3.

The information processing apparatus 1 is a computer which processes information at high speed according to procedures indicated in programs. The information processing apparatus 1 has five functions including input, storage, calculation, control and output. The input device 2 is a man-machine interface for inputting data to the information processing apparatus 1. Representative examples of the input device 2 include a keyboard, a mouse and other devices. The output device 3 is a man-machine interface for outputting results of processes in the information processing apparatus 1 to the outside. Representative examples of the output device 3 include a display, a printer and other devices.

The information processing apparatus 1 includes a central processing unit (CPU) 4, a random access memory (RAM) 5, and a large capacity storage 6 which are connected to each other via a bus 7. The CPU 4 controls various devices provided in the information processing apparatus 1 and processes data. The CPU 4 receives data inputted from the input device 2 via the bus 7, interprets the received data, performs calculation based on the received data, and outputs the results to the output device 3 or the like. The RAM 5 includes a storage medium and is used when the CPU 4 executes the software programs. The large capacity storage 6 is an information storage device exemplified by a hard disc device and a nonvolatile semiconductor memory. The large capacity storage 6 holds data stored therein until the data is deleted by a user.

The large capacity storage 6 includes a program storage region 8 and a data storage region 9. The program storage region 8 stores programs such as a behavioral synthesis tool 11, a clock-level power information extracting tool 12, a functional block power information extracting tool 13, and a behavioral-level power information extracting tool 14. The data storage region 9 stores data such as a behavioral-level C description 15, an RT-level (RTL) description 16, a clock-level description 17, control information 18, a power calculation formula file 19, functional block resister toggle information 21, a functional block power calculation formula file 22, a simulation description 23 as a description for simulation, and a system estimated power 24.

The behavioral-level C description 15 is a simulation model which describes operation of an integrated circuit (module) as an object of design by using a behavior level (BL). The behavioral-level C description 15 defines for each group of specific processes (hereinafter, the group of specific processes is referred to as functional block), time required for executing the functional block. The integrated circuit indicated by the behavioral-level C description 15 includes at least one semiconductor circuit design block which is called as intellectual property (IP) The IP includes at least one functional block. In the present embodiment, the behavioral-level C description 15 is described in a high-level programming language such as C or C++. However, this does not exclude case that the behavioral-level C description 15 is described in another programming language.

The RTL description 16 is obtained by behavioral synthesis. The RTL description 16 is a structural description which is described in hardware description language, and is subjected to logic synthesis to determine specific gate circuits of the integrated circuit (module) as the object of design. The RTL description 16 is a simulation model which describes the operation of the module. The operation is defined per cycle. The RTL description 16 can be converted to a gate-level description by the logic synthesis.

The clock-level description 17 is used for executing a simulation at a clock level which is lower than the behavioral level and higher than the RT level in abstraction degree. Resisters (or storage elements) and computing elements included in the clock-level description 17 are in one-to-one correspondence with resisters (or storage elements) and computing elements subsequently implemented as hardware by the logic synthesis based on the RTL description 16. The untimed operation of the semiconductor circuit as the object of design, which is described in the behavioral-level C description 15, is converted under a predetermined constraint into an operation per clock. The operation per clock is described in the clock-level description 17. The clock-level description 17 is a simulation model which describes the operation of the module (or semiconductor device as the object of design). The operation is defined per cycle. The present embodiment will be described by exemplifying a case where the clock-level description 17 is described in a programming language such as C or C++.

The control information 18 is outputted from the behavioral synthesis tool 11 and includes information of resource constraints in the behavioral synthesis. More specifically, the control information 18 includes information on variables in the behavioral-level C description 15, correspondence information on resister variables in the RTL description 16 and other information. For example, the control information 18, for each of the resisters, includes information that a state and a condition in a finite state machine (FSM) results in the change of the corresponding resister variable.

The power calculation formula file 19 is a file having data sheets (power calculation formulae) for obtaining power consumptions with respect to resisters (or storage elements) such as flip-flops and memories. The power calculation formulae include data relating to areas and operating frequencies of the resisters (or storage elements) when they are implemented as hardware. In the present embodiment, the power calculation formula file 19 is provided in advance as a library in which formula for calculating power consumption in each section is stored.

The functional block resister toggle information 21 indicates correspondence among functional blocks, resisters which constitute the functional blocks, and number of toggles of the resisters when the resisters are in states of the functional blocks. If the integrated circuit indicated in the above-described behavioral-level C description 15 has a plurality of intellectual properties (IPs), the functional block resister toggle information 21 is configured to correspond to each of the IPs. Each of the IPs includes at least one functional block. The functional block resister toggle information 21 includes information to obtain power consumption in each of the functional blocks. Here, the functional block means a group of certain processes. In the present embodiment, the functional block resister toggle information 21 may be configured such that granularity of the group is variable depending on operational modes (i.e. standby modes or operational modes), C-level syntactic units (i.e. brunch units of functions, if-statements or switch-statements) or the like.

The functional block power calculation formula file 22 has formulae for calculating power consumption. The functional block power calculation formula file 22 is generated based on the functional block resister toggle information 21 and the power calculation formula file 19 as data sheets (or power calculation formulae) to obtain power consumption with respect to specific functional blocks.

The simulation description 23 is a simulation model of modules constituting a system, and describes operations of IP cores such as CPU core included in the integrated circuit (or module) as the object of design, a bus model and the like. The simulation description 23 according to the present embodiment is capable of constituting the system in combination with the behavioral-level C description 15.

The system estimated power 24 is obtained by a system-level simulation using the behavioral-level C description 15 and is information of estimated power consumption of the integrated circuit (or module) as the object of design.

The behavioral synthesis tool 11 performs behavioral synthesis based on the behavioral-level C description 15 to generate the RTL description 16. The behavioral synthesis tool 11 also performs behavioral synthesis based on the behavioral-level C description 15 to generate the clock-level description 17. The behavioral synthesis tool 11 further generates the control information 18. The behavioral synthesis tool 11 according to the present embodiment configures the clock-level description 17 based on the control information 18 such that the clock-level description 17 includes time information indicating required time of operation of the functional block. The time information indicates a total required time of operation of a certain functional block. The clock-level description 17 indicates how the operation of the functional block is performed for respective time units in the total required time.

The clock-level power information extracting tool 12 is a device to obtain power information at a clock level. The clock-level power information extracting tool 12 includes a dynamic simulator, a device to calculate power consumption from simulation results, and a device to calculate static power consumption. The clock-level power information extracting tool 12 uses operating ratios obtained by simulations to calculate power consumption in each of the sections, such as resisters (or storage elements), computing elements and multiplexers which constitute the semiconductor device as the object of design, by referring to the power calculation formula file 19. The clock-level power information extracting tool 12 according to the present embodiment calculates the functional block resister toggle information 21 as the power information at the clock level. Although a case where the RTL description 16 is inputted to the clock-level power information extracting tool 12 is described as an example in the present embodiment, a gate-level description may be inputted to the clock-level power information extracting tool 12 in place of the RTL description 16.

The functional block power information extracting tool 13 performs a mapping of power per functional block based on the functional block resister toggle information 21 to generate the functional block power formula file 22. The operation level power information extracting tool 14 executes a simulation in which a behavioral-level model is used as an input to calculate power consumption of the system.

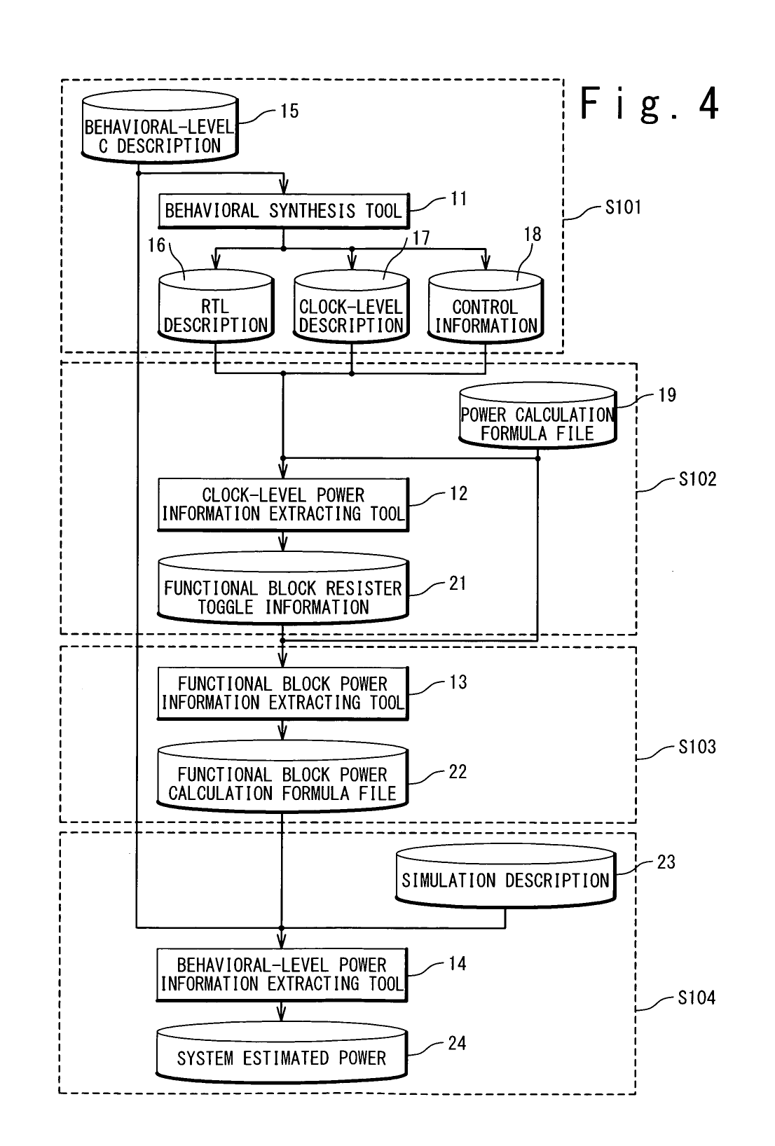

Operation according to the present embodiment will be described below. The operation of the present embodiment is implemented by the information processing apparatus 1 operating based on procedures indicated in the predetermined computer programs. FIG. 4 is a flowchart illustrating as an example the operation of the information processing apparatus 1. Steps S101 to S104 of the flowchart indicate an example of a chain of actions executable by the information processing apparatus 1 according to the present embodiment.

In the step S101, the information processing apparatus 1 causes the behavioral synthesis tool 11 to start. The behavioral synthesis tool 11 reads (or causes the CPU 4 to read) the behavioral-level C description 15 stored in the data storage region 9 to generate the RTL description 16, the clock-level description 17 and the control information 18. The outputs of the behavioral synthesis tool 11 will be described below.

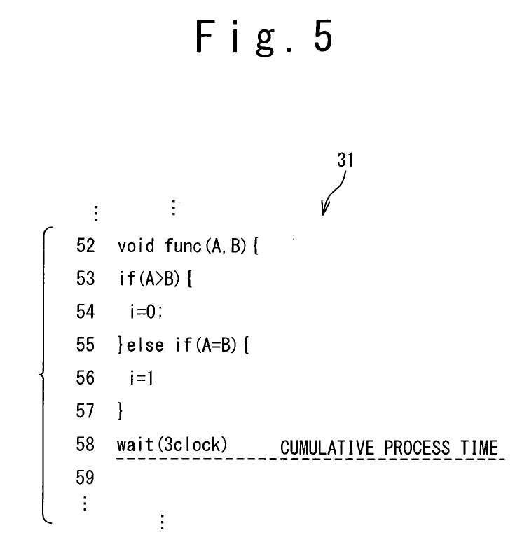

FIG. 5 exemplifies a configuration of the behavioral-level C description 15. A portion of the behavioral-level C description 15 is extracted and exemplified as a behavioral-level C description list 31 of FIG. 5. The behavioral-level C description 15 is a behavioral level description including a concept of time. The concept of time (or time information) of the behavioral-level C description 15 is not defined at cycle level and cumulative time is defined per functional block. Referring to FIG. 5, 58th line of the behavioral-level C description 15 (i.e. 7th line from the top of the behavioral-level C description list 31) indicates that a cumulative process time of the functional block is 3 clock. In the present embodiment, time information specified by “wait” of the behavioral-level C description 15 is considered in estimating power consumed in the IP.

The behavioral-level C description list 31 of FIG. 5 exemplifies a case that one function included in the behavioral-level C description 15 is one functional block. Since power consumption information is extracted for each functional block, “functional block=function” is given for the following descriptions. Meanwhile, when power consumption information is extracted per branch of if-statement, “functional block =branch of if-statement” is given.

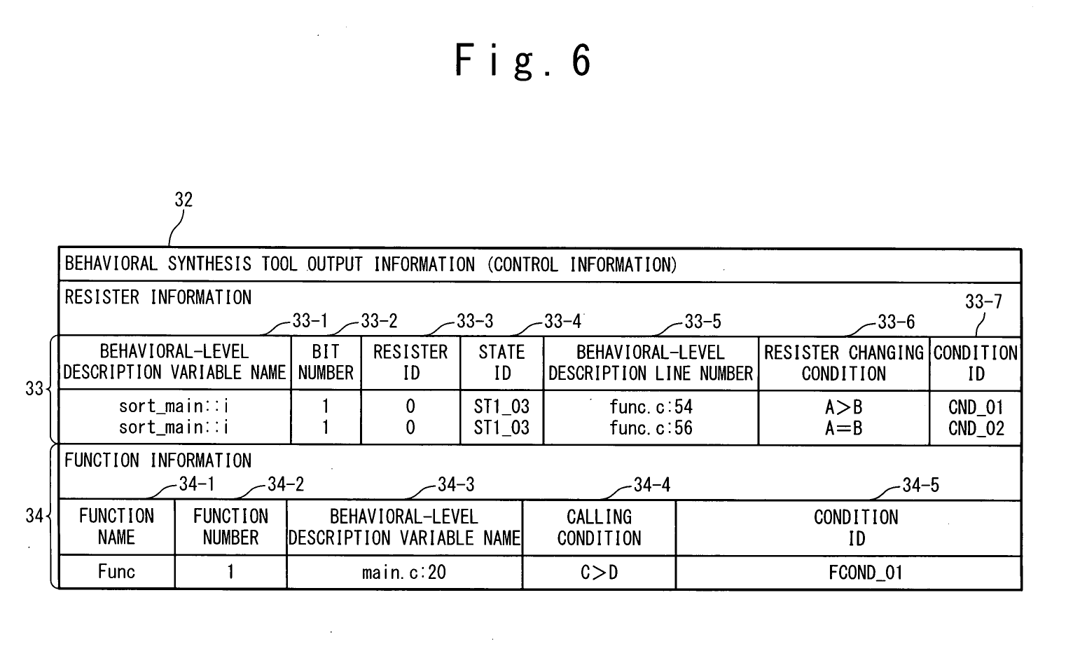

FIG. 6 exemplifies a configuration of the control information 18 outputted by the behavioral synthesis tool 11. In the present embodiment, the behavioral synthesis tool 11 generates (or causes the CPU 4 to generate) the control information 18 indicating correspondence between a description of the behavioral-level C description 15 before the behavioral synthesis and a resister in the clock-level description 17 generated after the behavioral synthesis. The control information 18 correlates the description of the behavioral-level C description 15 before the behavioral synthesis to a state transition of generated hardware (HW). FIG. 6 is a behavioral synthesis tool output information table 32 visualizing the configuration of the control information 18. As shown in FIG. 6, the control information 18 includes resister information 33 and function information 34.

The resister information 33 correlates a behavioral-level description variable name 33-1, a bit number 33-2, a resister identifier (resister ID) 33-3, a state identifier (state ID) 33-4, a behavioral-level description line number 33-5, a resister changing condition 33-6, and a condition identifier (condition ID) 33-7 from one another. The function information 34 correlates a function name 34-1, a function number 34-2, a behavioral-level description line number 34-3, and a condition identifier (condition ID) 34-5 from one another.

The behavioral-level description variable name 33-1 of the resister information 33 is a variable name converted to a resister as a result of the behavioral synthesis. As shown in FIG. 6, by referring to the control information 18, when the behavioral-level description variable name 33-1 is specified, it is made possible to extract the state ID 33-4 corresponding to a state of the FSM, the behavioral-level description line number 33-5 as a line number of a behavioral level model, and the resister changing condition 33-6 as a condition to change a value of the resister. As shown in FIG. 6, by referring to the control information 18, it is also made possible to extract the function number 34-1 indicating a function included in the behavioral level model and conditions (i.e. calling condition 34-4 and condition ID 34-5) to call the function.

As described later, the clock-level power information extracting tool 12 reads out and uses (or causes the CPU 4 to read out and use) the control information 18 outputted by the behavioral synthesis tool 11 to obtain operating ratios of resisters (or storage elements) per functional block.

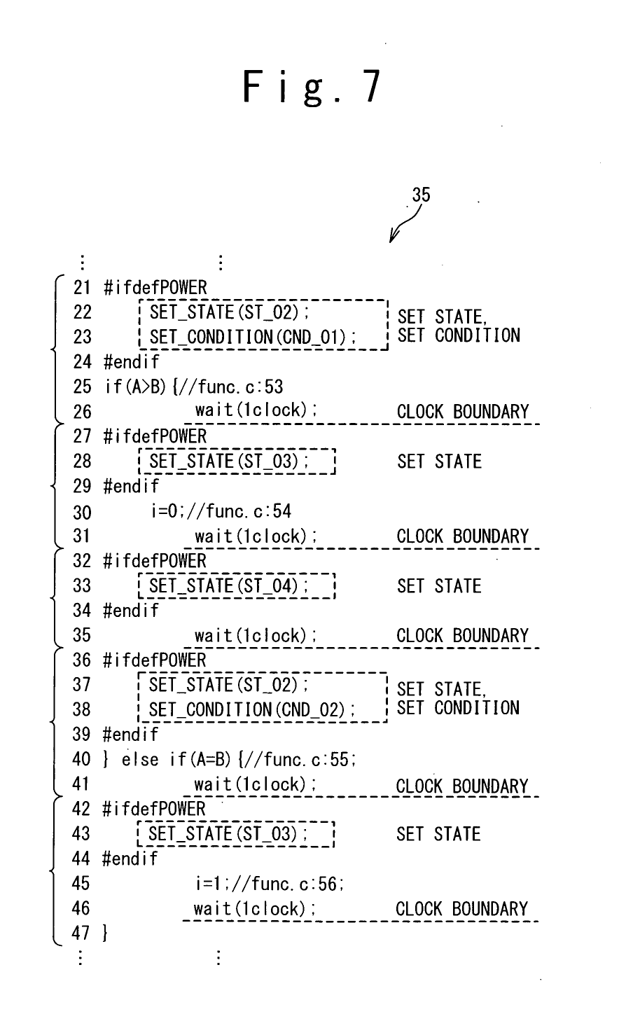

FIG. 7 exemplifies a configuration of the clock-level description 17 outputted by the behavioral synthesis tool 11. A portion of the clock-level description 17 is extracted as a list (i.e. clock-level description list 35) and a configuration of the list is exemplified in FIG. 7. The clock-level description 17 according to the present embodiment includes descriptions indicating the state ID 33-4 and the condition ID 33-7. Referring to the clock-level description list 35 of FIG. 7, 21st to 26th lines of the clock-level description 17 (or 1st line to 6th line from the top of the clock-level description list 35) correspond to description in 53rd line of the behavioral-level C description 15. Description in 22nd and 23rd lines of the clock-level description 17 (or 2nd to 3rd lines from the top of the clock-level description list 35) indicates that description in 53rd line of the behavioral-level C description 15 corresponds, after the behavioral synthesis, to the following:
STATE ID ST_{—}02
CONDITION ID CND_{—}01.
   In 17th to 31st lines of the clock-level description 17, it is indicated that description in 54th line of the behavioral-level C description 15 corresponds, after the behavioral synthesis, to the following:
STATE ID ST_{—}03.

Moreover, 32nd to 35th lines of the clock-level description 17 indicate that an idle cycle is inserted by the behavioral synthesis tool. Furthermore, 36th to 41st lines of the clock-level description 17 indicate that 55th line of the behavioral-level C description 15 corresponds, after the behavioral synthesis, to the following:
STATE ID ST_{—}02
CONDITION ID CND_{—}02.
   In 42nd to 47th lines of the clock-level description 17, it is indicated that description in 56th line of the behavioral-level C description 15 corresponds, after the behavioral synthesis, to the following:
STATE ID ST_{—}03.

Referring to FIG. 4, in the step S102, the information processing apparatus 1 causes the clock-level power information extracting tool 12 to start to estimate power consumption at the clock level. The clock-level power information extracting tool 12 executes (or causes the CPU 4 to execute) a simulation in which the control information 18 including functional block information, the clock-level description 17 including a description such as the clock-level description list 35 of FIG. 7, and the power calculation formula file 19 are used as inputs. At this time, whenever SET_STATE and SET_CONDITION are called, the clock-level power information extracting tool 12 has the information stored. It should be noted, in condition setting and state setting indicated in the clock-level description list 35, that inserted lines include a line not indicating change of resister. For example, if a same state (or same value) is continuously maintained corresponding to time elapses, the clock-level power information extracting tool 12 has information stored which indicates the resister is unchanged. The clock-level power information extracting tool 12 combines (or causes the CPU 4 to combine) this stored information with the control information 18 outputted by the behavioral synthesis to obtain number of changes each resister has made during execution of simulation.

The clock-level power information extracting tool 12 generates (or causes the CPU 4 to generate), per functional block, data which indicates the number of toggles (or operating ratio) of resisters (or storage elements). The clock-level power information extracting tool 12 generates (or causes the CPU 4 to generate) data as described above for each of the plurality of functional blocks belonging to the IP. The clock-level power information extracting tool 12 generate (or causes the CPU 4 to generate) functional block resister toggle information 21 which indicates estimated power consumption of the IP at the clock level based on these data. When the integrated circuit as the object of design includes the plurality of IPs, the clock-level power information extracting tool 12 generates (or causes the CPU 4 to generate) the functional block resister toggle information 21 for each of the plurality of the IPs.

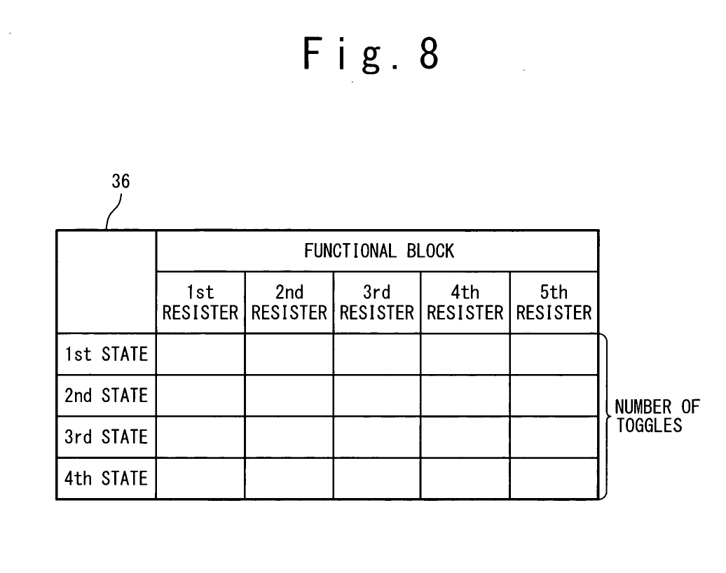

FIG. 8 is a table (hereinafter, referred to as estimated power consumption data table 36) exemplifying estimated power consumption data which indicates power consumed in the functional block. The functional block resister toggle information 21 includes the estimated power consumption data table 36 for each of the plurality of functional blocks belonging to the IP. Referring to FIG. 8, the estimated power consumption data table 36 is configured such that the number of toggles of the resisters (or storage elements) constituting a functional block is obtained when the resisters (or storage elements) and a state of the functional block are specified. Granularities, such as specific operation mode, state transition, function in the behavioral-level model, and internal branching unit, of the functional block can be selected. The clock-level power information extracting tool 12 can obtain (or cause the CPU 4 to obtain) number of calls of the function or the like and obtain number of changes through consideration of condition. The clock-level power information extracting tool 12 executes (or causes the CPU 4 to execute) simulations such as estimating method based on a dynamic simulation using RTL and clock-level model of C language, and static estimation method using RTL. In the present embodiment, any method may be employed as long as calculation in the method is based on operating ratios of the resisters (or storage elements) included in the semiconductor device as the object of design.

Referring to FIG. 4, in the step S103, the functional block power information extracting tool 13 executes (or causes the CPU 4 to execute) mapping of the estimated power consumption of the IP at the clock level indicated in the functional block resister toggle information 21 to the functional block of the behavioral-level C description 15. The functional block power information extracting tool 13 obtains (or causes the CPU 4 to obtain) correspondence between the functional block and resisters (or storage elements) included therein by referring to the functional block resister toggle information 21, and obtains (or causes the CPU 4 to obtain) power consumption calculation formulae per functional block by using the correspondence. The calculation formulae include a calculation formula of total power consumption per functional block with clock frequency being considered and a calculation formula of average power consumption value obtained based on time information defined in the functional block.

The functional block power information extracting tool 13 reads out (or causes the CPU 4 to read out) the power calculation formulae prepared in accordance with types of the resisters (or storage elements) from the power calculation formula file 19 to calculate power consumption. As described above, the power calculation formula file 19 includes the data of areas and operating frequencies of the resisters when they are implemented as hardware. The power calculation formula file 19 is configured to allow calculation of power consumed in a single operation of the resister (or storage element) based on the data. The functional block power information extracting tool 13 estimates (or causes the CPU 4 to estimate) power used by flip-flops and computing elements included in the functional block, and leak current based on the power calculation formulae obtained by referring to the power calculation formula file 19 and the functional block resister toggle information 21. The functional block power information extracting tool 13 calculates (or causes the CPU 4 to calculate) a functional block power consumption which is power consumed in a single execution of the functional block from the following formula (1):

Functional block power consumption=Σ (average power consumption of a resister in the functional block)+Σ (average power consumption of a computing element other than the resisters in the functional block) (1)

As described above, the functional block power information extracting tool 13 generates (or causes the CPU 4 to generate) the functional block power calculation formula file 22 based on the formula (1). The functional block power calculation formula file 22 thus generated is held in the data storage region 9 of the information processing apparatus 1 as a library.

In the step S104, the behavioral-level power information extracting tool 14 executes (or causes the CPU 4 to execute) a simulation using the behavioral-level C description 15 including the time information to generate the system estimated power 24. At this time, the behavioral-level power information extracting tool 14 calculates (or causes the CPU 4 to calculate) operating ratios of the functional blocks (i.e. number of calls of the functional blocks) of the behavioral-level C description 15 during execution of the simulation. The behavioral-level power information extracting tool 14 estimates (or causes the CPU 4 to estimate) total power consumption as power consumed in entire of the integrated circuit as the object of design based on the operating rations, the power consumption calculation formula per functional block and the following formula (2):

Total power consumption=Σ (product of operating ratio of a functional block and power consumption value of the functional block)+leak current of the module (2)

As described above, the behavioral-level power information extracting tool 14 calculates (or causes the CPU 4 to calculate) the total power consumption. The behavioral-level power information extracting tool 14 has the total power consumption stored as the system estimated power 24 in the data storage region 9.

In other words, in the present embodiment, the predicted value of power consumption of the semiconductor device as the object of design is calculated by simulating the operation of the semiconductor device as the object of design based on the behavioral-level model which includes the time information. The operating ratios of the functional blocks indicated in the behavioral description are calculated, and then, the predicted value is calculated based on the calculated operating ratios and the power consumption calculation formulae respectively corresponding to the clock frequencies. The means for calculating the predicted value calculates the predicted value of power consumption of each functional block constituting the IP based on an assumption that the functional model operates when the functional block is called. The means for calculating the predicted value calculates the predicted value of power consumption based on the operating ratios of the functional blocks, which are calculated during execution of the simulation. In case of no operation being called at all, the predicted value of power consumption is calculated based on a power consumption calculation formula corresponding to the case and duration in which no operation is called.

According to the power consumption calculating method described above, as for the functional blocks of the behavioral-level description, one functional block is a unit for setting the time information in the behavioral-level model. For the functional block as the unit, the power value to be consumed is calculated as a sum of the estimated power values obtained from the result of the simulation of the clock-level description.

When one functional block is assumed to be a unit for adding time information in the behavioral-level model, for each functional block, the power consumption calculation formula is obtained from the result of the simulation of the clock-level description. In a process of calculating the predicted value, the calculation is preferably made on an assumption that each functional block operates only when the functional block is called. Furthermore, in the process of calculating the predicted value, the predicted value of power consumption may be calculated based on the power calculation formula in case that no operation is called at all and duration in which no operation is called.

The information processing apparatus 1 according to the present embodiment calculates the total power consumption by using the power consumption obtained by the simulation at the clock level. Therefore, the entire power consumption can be obtained with high accuracy. The information processing apparatus 1 according to the present embodiment is capable of estimating the power consumption with sufficient accuracy in an initial stage for considering architecture.

The information processing apparatus 1 according to the present embodiment executes the simulation by using the behavioral-level model. Accordingly, the power consumption of the system can be obtained at high speed even if the simulation at the clock-level requires a longer time as the size of the system increases.

The above described embodiment was exemplified by using a case that the behavioral synthesis tool 11 outputs (or causes the CPU 4 to output) the clock-level description 17 which includes descriptions indicating the state ID 33-4 and the condition ID 33-7. The present invention is not limited to the above described embodiment. For example, the RTL description 16 may includes the descriptions indicating the state ID 33-4 and the condition ID 33-7. In this case, the power is preferably calculated by mapping the resisters (or storage elements) at the RT level to actual hardware by using a tool to obtain power consumption at the RT level and a library for logic synthesis.

The functional blocks are configured such that the granularities such as specific operation mode, state transition, function in the behavioral-level model, and internal branching unit are can be selected. In this case, the functional blocks are preferably configured by setting portions of description in which number of changes of the resister is largely changed in the behavioral-level C description 15 as sections separating one functional block from another.

As described above, the behavioral-level C description 15 defines required time to execute functional block constituting the integrated circuit. In the above embodiment, the behavioral synthesis tool 11 configures (or causes the CPU 4 to configure) the clock-level description 17 which includes the time information indicating the required time of operation of the functional block. In the power consumption calculating apparatus 10 according to the present embodiment, the behavioral synthesis tool 11 can output (cause the CPU 4 to output) the clock-level description 17 (or RTL description 16) without depending on the time information. At this time, the behavioral synthesis tool 11 generates (or causes the CPU 4 to generate) the RTL description 16 or the clock-level description 17 such that no time information is included therein. The clock-level power information extracting tool 12 generates (or causes the CPU 4 to generate) the functional block resister toggle information 21 by using the RTL description 16 or the clock-level description 17. In this case, the functional block power information extracting tool 13 is preferably configured to generate (or cause the CPU 4 to generate) the functional block power calculation formula file 22 based on the time information defined in the operation-level C description 15 and the functional block resister toggle information 21. Therefore, the power consumption calculating apparatus 10 according to the present embodiment is capable of generating the system estimated power 24 appropriately even in the case that the behavioral synthesis tool 11 performs (or causes the CPU 4 to perform) behavioral synthesis without the constraints of time defined in the behavioral-level C description 15.

The above embodiments can be described as the following example. In the following example, each numeral in a pair of parentheses indicates the corresponding element indicated by the same numeral in the accompanying drawings. But elements in the following example are not limited to the corresponding elements.

A power consumption calculating method is provided to calculate power consumption of an integrated circuit (15) including at least one functional block. The power consumption calculating method includes: configuring a low-level circuit model (17) described at lower degree of abstraction than a behavioral level from the integrated circuit described at the behavioral level; generating operation information (21) indicating operation of the functional block based on the low-level circuit model; obtaining functional block power consumption (22) as power consumption of the functional block based on the operation information and element power consumption (19) as power consumption of elements constituting the functional block; and obtaining entire power consumption (24) as power consumption of the integrated circuit based on the functional block power consumption and number of times the functional block is executed in operation of the integrated circuit.

In the calculating method, when the power consumption of the integrated circuit described at the behavioral level is obtained, power consumption is obtained for each functional block at the lower degree of abstraction by one grade than the behavioral level. Information indicating the power consumptions is held as a library. When a simulator reads out a statement corresponding to the functional block in execution of a simulation using the behavioral-level description, power consumption corresponding to the read-out statement is obtained by referring to the library. Power consumption of entire of the integrated circuit is estimated based on number of calls of the functional block and the power consumption stored as the library in advance.

According to the above example, it is made possible to estimate power consumption of a semiconductor device in a short period of time.

It is apparent that the present invention is not limited to the above embodiments, but may be modified and changed without departing from the scope and spirit of the invention.

What is claimed is:

1. A power consumption calculating method comprising:
generating operation information indicating operation of a functional block based on a low-level circuit model by configuring said low-level circuit model from a behavioral-level circuit model describing an integrated circuit at a behavioral level and having at least one functional block including said functional block wherein said low-level circuit model describes said integrated circuit at lower degree of abstraction than said behavioral level;
obtaining functional block power consumption as power consumption of said functional block based on said operation information and element power consumption as power consumption of element group constituting said functional block; and
obtaining entire power consumption of said integrated circuit based on said functional block power consumption and number of times said functional block is executed in operation of said integrated circuit.

2. The power consumption calculating method according to claim 1, wherein said generating said operation information includes:
generating said low-level circuit model by performing behavioral synthesis based on said integrated circuit model such that said low-level circuit model includes time information indicating required time of said operation of said functional block; and
generating said operation information based on said operation of said low-level circuit model at time units by executing a simulation of said low-level circuit model.

3. The power consumption calculating method according to claim 2, wherein said time information indicates total required time of said operation of said functional block, and
said low-level circuit model indicates said operation of said functional block at said time units in said total required time.

4. The power consumption calculating method according to claim 1, wherein said generating said operation information includes:
outputting control information indicating correspondence between said integrated circuit model and said low-level circuit model; and
generating said operation information based on said control information.

5. The power consumption calculating method according to claim 1, wherein said obtaining said functional block power consumption includes:
extracting number of times said element group operates in said operation of said functional block from said operation information; and
calculating said functional block power consumption based on said number and power consumption in a single operation of said element group.

6. The power consumption calculating method according to claim 5, wherein said element group include a plurality of resisters,
said functional block power consumption indicates a sum of a plurality of power consumptions of said plurality of resisters,
each of said plurality of said power consumptions indicates a product of a first power consumption and a first number,
said first power consumption is power consumption in a single operation of one of said plurality of resisters, and
said first number is number of times said one of said plurality of resisters operates.

7. The power consumption calculating method according to claim 1, wherein said obtaining said entire power consumption includes:
executing a simulation of said behavioral-level circuit model;
counting number of times said functional block is executed during executing said simulation; and
obtaining said entire power consumption based on a product of said number and said functional block power consumption.

8. A computer-readable recording medium which records a program that when executed causes a computer to perform a method comprising:
generating operation information indicating operation of a functional block based on a low-level circuit model by configuring said low-level circuit model from a behavioral-level circuit model describing an integrated circuit at a behavioral level and having at least one functional block including said functional block wherein said low-level circuit model describes said integrated circuit at lower degree of abstraction than said behavioral level;
obtaining functional block power consumption as power consumption of said functional block based on said operation information and element power consumption as power consumption of element group constituting said functional block; and
obtaining entire power consumption of said integrated circuit based on said functional block power consumption and number of times said functional block is executed in operation of said integrated circuit.

9. The computer-readable recording medium according to claim 8, wherein said generating said operation information includes:
generating said low-level circuit model by performing behavioral synthesis based on said integrated circuit model such that said low-level circuit model includes time information indicating required time of said operation of said functional block; and
generating said operation information based on said operation of said low-level circuit model at time units by executing a simulation of said low-level circuit model.

10. The computer-readable recording medium according to claim 9, wherein said time information indicates total required time of said operation of said functional block, and
said low-level circuit model indicates said operation of said functional block at said time units in said total required time.

11. The computer-readable recording medium according to claim 8, wherein said generating said operation information includes:
outputting control information indicating correspondence between said integrated circuit model and said low-level circuit model; and
generating said operation information based on said control information.

12. The computer-readable recording medium according to claim 8, wherein said obtaining said functional block power consumption includes:
extracting number of times said element group operates in said operation of said functional block from said operation information; and
calculating said functional block power consumption based on said number and power consumption in a single operation of said element group.

13. The computer-readable recording medium according to claim 12, wherein said element group include a plurality of resisters,
said functional block power consumption indicates a sum of a plurality of power consumptions of said plurality of resisters,
each of said plurality of said power consumptions indicates a product of a first power consumption and a first number,
said first power consumption is power consumption in a single operation of one of said plurality of resisters, and
said first number is number of times said one of said plurality of resisters operates.

14. The computer-readable recording medium according to claim 8, wherein said obtaining said entire power consumption includes:
executing a simulation of said behavioral-level circuit model;
counting number of times said functional block is executed during executing said simulation; and
obtaining said entire power consumption based on a product of said number and said functional block power consumption.

15. A library generating method comprising:
specifying a functional block as an object of generating a library from a plurality of functional blocks included in an integrated circuit model described at a behavioral level;
generating operation information indicating operation of said functional block based on a low-level intellectual property (IP) model by behavioral-synthesizing an intellectual property (IP) model including said functional block specified and by describing said low-level IP model including time information indicating required time of operation of said functional block at lower degree of abstraction than said behavioral level;
generating a functional block power calculation formula indicating power consumed in said functional block based on said operation information and a power calculation formula indicating power consumed in element group constituting said functional block; and
configuring said library by generating a functional block power calculation formula for each of said plurality of functional blocks.

16. The library generating method according to claim 15, wherein said time information indicates total required time of said operation of said functional block,
said low-level IP model indicates said operation of said functional block at time units in said total required time, and
said generating said operation information includes:
outputting control information indicating correspondence between said integrated circuit model and said low-level IP model; and
generating said operation information based on said control information and operation of said low-level IP model at time units obtained by executing a simulation of said low-level IP model.

17. The library generating method according to claim 15, wherein said generating said functional block power calculation formula includes:
extracting number of times said element group operates in said operation of said functional block from said operation information, and
generating said functional block power calculation formula based on said number and power consumption in a single operation of said element group.

18. The library generating method according to claim 17, wherein said element group includes a plurality of resisters,
said functional block power calculation formula indicates a sum of a plurality of power consumptions of said plurality of resisters,
each of said plurality of said power consumptions is a product of a first power consumption and a first number,
said first power consumption is power consumption in a single operation of one of said plurality of resisters, and
said first number is number of times said one of said plurality of resisters operates.
